(19) United States
(12) Patent Application Publication
(10) Pub. No.: US 2026/0150730 A1
(43) Pub. Date: May 28, 2026

(54) PACKAGE SUBSTRATE AND SEMICONDUCTOR PACKAGE

(71) Applicant: SAMSUNG ELECTRONICS CO., LTD., Suwon-si (KR)

(72) Inventors: Keunyoung LEE, Suwon-si (KR); Hyeongseok Kang, Suwon-si (KR); Dongok Kwak, Suwon-si (KR)

(73) Assignee: SAMSUNG ELECTRONICS CO., LTD., Suwon-si (KR)

(21) Appl. No.: 19/184,535

(22) Filed: Apr. 21, 2025

(30) Foreign Application Priority Data
Oct. 11, 2024 (KR) 10-2024-0138793

(51) Int. Cl. H01L 23/538; H01L 23/00; H01L 23/498; H01L 25/07

(52) U.S. Cl. CPC H10W 70/65; H10W 70/611; H10W 70/66; H10W 72/20; H10W 90/00; H10W 90/701; H10W 90/724; H10W 90/754

(57) ABSTRACT

A package substrate includes a base substrate, a plurality of chip connection pads on an upper surface of the base substrate, a plurality of interconnection patterns on the upper surface of the base substrate and coupled with the plurality of chip connection pads, and an insulating layer on the plurality of interconnection patterns. The insulating layer includes a solder resist layer and at least one opening. The at least one opening at least partially exposes a connection portion. The connection portion includes at least a portion of a first interconnection pattern from among the plurality of interconnection patterns.

### CROSS-REFERENCE TO RELATED APPLICATIONS

This application claims priority under 35 U.S.C. § 119 to Korean Patent Application No. 10-2024-0138793, filed on Oct. 11, 2024, in the Korean Intellectual Property Office, the disclosure of which is incorporated by reference herein in its entirety.

### BACKGROUND

The present disclosure relates generally to package substrates, and more particularly, to a package substrate with an open stub and a semiconductor package including the same.

A semiconductor package may include a semiconductor chip and a package substrate on which the semiconductor chip is mounted, and the package substrate may include an interconnection pattern for transmitting a signal of the semiconductor chip, or the like. In a process in which the interconnection pattern transmits a signal, a reflected wave may occur within the interconnection pattern. A characteristic degradation phenomenon in which an eye margin of the transmitted signal is reduced may occur due to the reflected wave within the interconnection pattern. Attempts to address the degradation phenomenon may include the use of controlled open stub (COS) technology. For example, the COS technology may improve characteristics of the signal transmitted by the interconnection pattern by adding an open stub to the interconnection pattern. However, the creation of an open stub as a pattern in the process of manufacturing the package substrate may result in the re-manufacturing of a new package substrate reflecting the open stub if the length of the open stub is changed, for example, to improve the characteristics of the signal transmitted by the interconnection pattern.

### SUMMARY

One or more example embodiments of the present disclosure provide a package substrate and a semiconductor package including the same, in which signal characteristics of semiconductor chips of various specifications may be optimized without design change, by selectively connecting wires to at least a portion of an interconnection pattern exposed externally by removing a portion of an insulating layer covering the interconnection pattern and/or controlling the number of wires to be connected.

According to an aspect of the present disclosure, a package substrate includes a base substrate, a plurality of chip connection pads on an upper surface of the base substrate, a plurality of interconnection patterns on the upper surface of the base substrate and coupled with the plurality of chip connection pads, and an insulating layer on the plurality of interconnection patterns. The insulating layer includes a solder resist layer and at least one opening. The at least one opening at least partially exposes a connection portion. The connection portion includes at least a portion of a first interconnection pattern from among the plurality of interconnection patterns.

According to an aspect of the present disclosure, a semiconductor package includes a package substrate and a plurality of semiconductor chips mounted on an upper portion of the package substrate. The package substrate includes a base substrate, a plurality of chip connection pads on an upper surface of the base substrate, a plurality of interconnection patterns on the upper surface of the base substrate and coupled with the plurality of chip connection pads, and an insulating layer on a surface of the plurality of interconnection patterns. The insulating layer includes at least one opening. The at least one opening at least partially exposes a connection portion. The connection portion includes at least a portion of a first interconnection pattern from among the plurality of interconnection patterns. A first semiconductor chip from among the plurality of semiconductor chips coupled with first chip connection pads from among the plurality of chip connection pads. A second semiconductor chip from among the plurality of semiconductor chips is coupled with second chip connection pads from among the plurality of chip connection pads.

According to an aspect of the present disclosure, a semiconductor package includes a package substrate, a plurality of semiconductor chips mounted on an upper portion of the package substrate, and a plurality of solder balls including a first solder ball. The package substrate includes a base substrate, a plurality of chip connection pads on an upper surface of the base substrate, a plurality of interconnection patterns on the upper surface of the base substrate and coupled with the plurality of chip connection pads, and an insulating layer on a surface of the plurality of interconnection patterns. The insulating layer includes at least one or more openings. At least one of the at least one or more openings at least partially exposing a connection portion. The connection portion includes at least a portion of a first interconnection pattern from among the plurality of interconnection patterns. The first solder ball is coupled with the first interconnection pattern and a test pad.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description, taken in conjunction with the accompanying drawings, in which:

FIGS. 1 and 2 are drawings illustrating package substrates, according to example embodiments;

FIGS. 3 to 5 are cross-sectional views illustrating the package substrate of FIG. 2 taken along line I-I′, according to example embodiments;

FIG. 6 is a drawing illustrating a package substrate, according to an example embodiment;

FIG. 7 is a drawing illustrating a package substrate, according to an example embodiment;

FIG. 8 is a perspective view illustrating an enlarged portion R of FIG. 7, according to an example embodiment;

FIG. 9 is a drawing illustrating a package substrate, according to an example embodiment;

FIG. 10 is a perspective view illustrating an enlarged portion R′ of FIG. 9, according to an example embodiment;

FIG. 11 is a drawing illustrating a package substrate, according to an example embodiment;

FIG. 12 is a perspective view illustrating an enlarged portion R″ of FIG. 11, according to an example embodiment;

FIGS. 13 and 14 are drawings illustrating semiconductor packages, according to example embodiments;

FIG. 15 is a cross-sectional view illustrating the package substrate of FIG. 14 taken along line II-II′, according to an example embodiment;

FIGS. 16 and 17 are drawings illustrating semiconductor packages, according to example embodiments; and

FIG. 18 is a cross-sectional view illustrating the package substrate of FIG. 17 taken along line III-III′, according to an example embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “exposing” another element or layer, the element or layer may expose at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language is used. For example, the term “a wire” may refer to either a single wire or multiple wires. When a wire is described as carrying a signal and the wire is referred to carry an additional signal, the multiple signals may be carried by either a single wire or any one or a combination of multiple wires.

Hereinafter, various embodiments of the present disclosure are described with reference to the accompanying drawings.

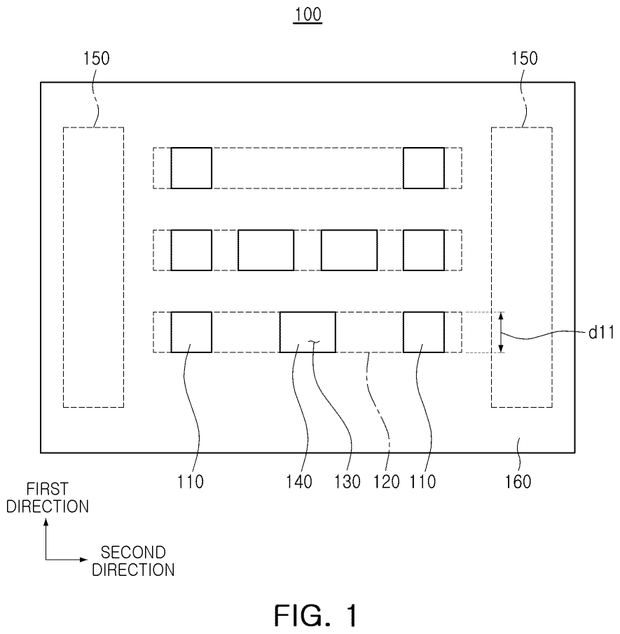

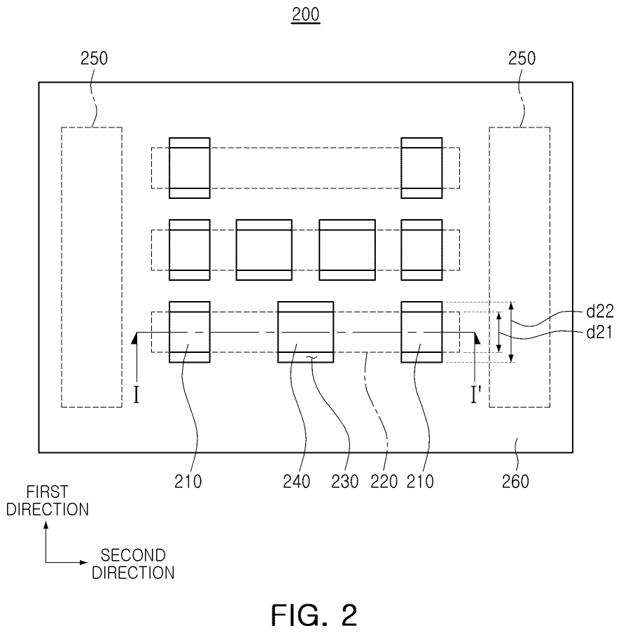

FIGS. 1 and 2 are drawings illustrating a package substrate, according to an example embodiment.

Referring to FIG. 1, a package substrate 100, according to an example embodiment, may include a base substrate, a plurality of chip connection pads 110, a plurality of interconnection patterns 120, an insulating layer 160 disposed on the plurality of interconnection patterns 120, or the like. The package substrate 100 may include a semiconductor chip mounting area 150 on which a semiconductor chip is mounted. For example, a semiconductor chip may be disposed on the semiconductor chip mounting area 150 and electrically connected to at least some of the plurality of interconnection patterns 120 by, for example, flip chip bonding and/or wire bonding.

The plurality of chip connection pads 110 may be disposed on the upper surface of the base substrate and may not be covered by the insulating layer 160, and as a result, may be exposed to the outside. A plurality of interconnection patterns 120 may be disposed on the upper surface of the base substrate and may be physically and electrically connected to a plurality of chip connection pads 110.

The insulating layer 160 may be disposed on the plurality of interconnection patterns 120 and may not be disposed on the plurality of chip connection pads 110. The insulating layer 160 may include at least one opening 130. The opening 130 may expose a connection portion 140 that is at least a portion of a first interconnection pattern 120 from among the plurality of interconnection patterns 120 to the outside. The first interconnection pattern 120 may have a first width d11 in a first direction parallel to the upper surface of the base substrate. In an example embodiment, as illustrated in FIG. 1, the width of the opening 130 in the first direction may be substantially similar and/or equal to the first width d11 of the first interconnection pattern 120. In addition, at least one of the plurality of chip connection pads 110 may have a first width d11 in the first direction.

Referring to FIG. 2, a package substrate 200, according to an example embodiment, may include a base substrate, a plurality of chip connection pads 210, a plurality of interconnection patterns 220, an insulating layer 260 disposed on the plurality of interconnection patterns 220, or the like. The architecture of the package substrate 200 may be similar in many respects to the package substrate 100 described above with reference to FIG. 1, and may include additional features not mentioned above. Furthermore, the base substrate, the plurality of chip connection pads 210, the plurality of interconnection patterns 220, and the insulating layer 260 may include and/or may be similar in many respects to the base substrate, the plurality of chip connection pads 110, the plurality of interconnection patterns 120, and the insulating layer 160 described above with reference to FIG. 1, respectively, and may include additional features not mentioned above. Consequently, repeated descriptions of the package substrate 200 and its components described above with reference to FIG. 1 may be omitted for the sake of brevity.

The package substrate 200 may include a semiconductor chip mounting area 250 on which a semiconductor chip may be mounted. For example, the semiconductor chip may be disposed on the semiconductor chip mounting area 250 and may be electrically connected to at least some of the plurality of interconnection patterns 220 by flip chip bonding and/or wire bonding, for example.

The plurality of chip connection pads 210 may be disposed on the upper surface of the base substrate and may not be covered by the insulating layer 260, and as a result, may be exposed to the outside. A plurality of interconnection patterns 220 may be disposed on the upper surface of the base substrate and may be physically and electrically connected to a plurality of chip connection pads 210.

An insulating layer 260 may be disposed on the plurality of interconnection patterns 220 and may not be disposed on the plurality of chip connection pads 210. The insulating layer 260 may include at least one opening 230. The opening 230 may expose a connection portion 240 that is at least a portion of a first interconnection pattern 220 from among the plurality of interconnection patterns 220 to the outside.

In an example embodiment, as shown in FIG. 2, the width of the opening 230 may be different from the width of each of the plurality of interconnection patterns 220. The first interconnection pattern 220 may have a first width d21 in a first direction parallel to the upper surface of the base substrate. The opening 230 may have a second width d22 that may be longer than the first width d21 in the first direction. At least one of the plurality of chip connection pads 210 may have the first width d21 in the first direction.

As illustrated in FIGS. 1 and 2, the insulating layer (e.g., the insulating layer 160 or the insulating layer 260) of the package substrate (e.g., the package substrate 100 or the package substrate 200), according to an example embodiment, may include at least one opening (e.g., the opening 130 or the opening 230) that may expose at least a portion of the connection portion (e.g., the connection portion 140 or the connection portion 240) from among the plurality of interconnection patterns (e.g. the plurality of interconnection patterns 120 or the plurality of interconnection patterns 220) to the outside. For example, in a state where the connection portion is exposed to the outside by the opening, a conductive pattern such as a wire and/or a metal nano ink pattern may be connected to the first interconnection pattern through the connection portion.

The conductive pattern connected to the first interconnection pattern may act as an inductance and/or a capacitance to the semiconductor chip electrically connected to the first interconnection pattern, thereby changing the impedance of the first interconnection pattern. Consequently, by selectively connecting the conductive pattern to the first interconnection pattern and/or adjusting the length of the conductive pattern while the semiconductor chip is mounted on the package substrate, the characteristics of the signal transmitted to the first interconnection pattern, such as, but not limited to, an eye margin, may be optimized.

In such a manner, in an example embodiment, the characteristics of the signal transmitted to the first interconnection pattern may be improved, when compared to a related package substrate, by additionally connecting the conductive pattern to the first interconnection pattern and/or adjusting the length of the conductive pattern. Therefore, even after the design and manufacturing of the package substrate are completed and the semiconductor chip is mounted, the performance of the semiconductor package including the package substrate may be optimized by referring to the results of the test work, thereby potentially improving the versatility and/or reliability of the package substrate.

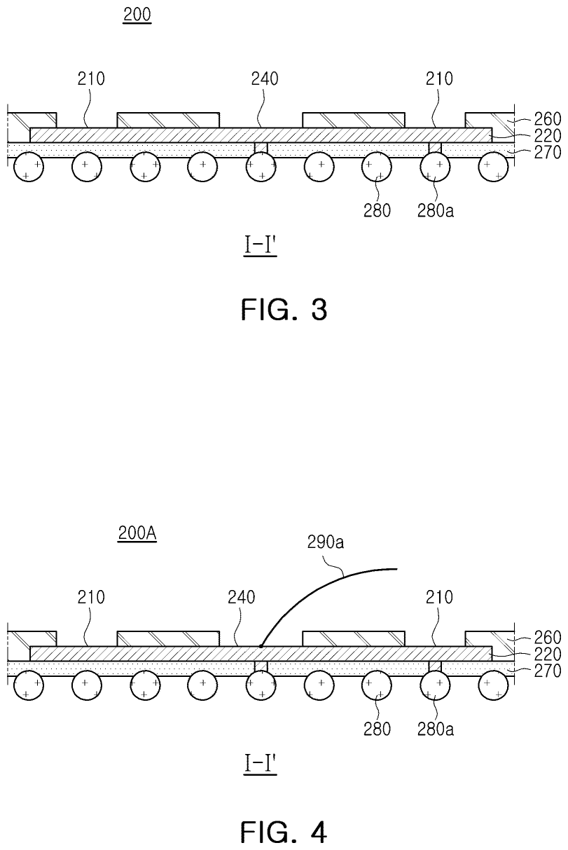

FIGS. 3 to 5 are cross-sectional views illustrating the package substrate of FIG. 2 taken along line I-I′. The cross-sectional structure described with reference to FIGS. 3 to 5 may also be applied to the package substrate 100 in which the opening 130 has the same first width d11 as the interconnection pattern 120 as shown in FIG. 1.

Referring to FIG. 3, a package substrate 200, according to an example embodiment, may include a base substrate 270, a plurality of chip connection pads 210, a plurality of interconnection patterns 220, an insulating layer 260 disposed on the plurality of interconnection patterns 220, a plurality of solder balls 280, or the like. The plurality of solder balls 280 may be disposed under the base substrate 270. At least one first solder ball 280a of the plurality of solder balls 280 may be electrically connected to the first interconnection pattern 220.

Referring to FIG. 4, a package substrate 200A, according to an example embodiment, may include a base substrate 270, a plurality of chip connection pads 210, a plurality of interconnection patterns 220, an insulating layer 260 disposed on the plurality of interconnection patterns 220, a plurality of solder balls 280, and a wire 290a. The architecture of the package substrate 200A may be similar in many respects to the package substrate 200 described above with reference to FIGS. 2 and 3, and may include additional features not mentioned above. Some of the elements of the package substrate 200A described above have been omitted for the sake of simplicity. For example, the package substrate 200A may have a structure in which a wire 290a is added to the package substrate 200.

The wire 290a may be electrically connected to the first interconnection pattern 220 through the connection portion 240. Although FIG. 4 illustrates the package substrate 200A as having one (1) 290a, the present disclosure does not limited in this regard. That is, the package substrate 200A may include two (2) or more wires 290a without departing from the scope of the present disclosure.

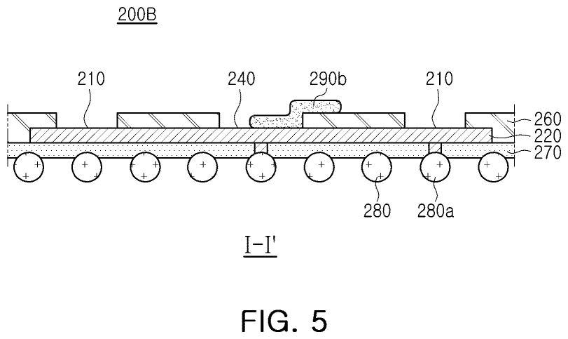

Referring to FIG. 5, the package substrate 200B, according to an example embodiment, may include a base substrate 270, a plurality of chip connection pads 210, a plurality of interconnection patterns 220, an insulating layer 260 disposed on the plurality of interconnection patterns 220, a plurality of solder balls 280, and a metal nano ink pattern 290b. The architecture of the package substrate 200B may be similar in many respects to the package substrate 200 described above with reference to FIGS. 2 and 3, and may include additional features not mentioned above. Some of the elements of the package substrate 200B described above have been omitted for the sake of simplicity. For example, the package substrate 200B, may have a structure in which a metal nano ink pattern 290b is added to the package substrate 200 or to the package substrate 200A.

The metal nano ink pattern 290b may be electrically connected to the first interconnection pattern 220 through a connection portion 240. The metal nano ink pattern 290b may be formed of silver (Ag). However, the material forming the metal nano ink pattern 290b may vary depending on an example embodiment.

The first interconnection pattern 220 may be electrically connected to the first solder ball 280a and thus may be electrically connected to the test pad. When a semiconductor chip is mounted in the semiconductor chip mounting area 250, the semiconductor chip may receive a test signal from the test equipment and/or transmit a signal to the test equipment through the first interconnection pattern 220, the first solder ball 280a, and the test pad.

While the semiconductor chip receives and/or transmits the test signal, the test equipment may measure the characteristics of the test signal, such as, but not limited to, the eye margin. For example, the test equipment may measure the eye margin indicating the transient characteristics of the test signal. Alternatively or additionally, the test equipment may measure other transient characteristics of the test signal that may include, amplitude, signal-to-noise ratio, jitter, delay, rise time, fall time, or the like.

If the eye margin of the test signal measured by the test equipment does not meet a predetermined standard (e.g., a threshold), the package substrate 200 including the first interconnection pattern 220 may be determined to have a defect that may cause a defect in the semiconductor package. For example, if the eye margin of the signal decreases in the process of semiconductor chips mounted on the package substrate 200 exchanging signals with the first interconnection pattern 220, the semiconductor chips may not be able to completely receive data included in the signal transmitted through the first interconnection pattern 220.

Therefore, if it is determined that the eye margin of the test signal transmitted through the first interconnection pattern 220 does not meet the standard, and as a result, the design of the package substrate 200 may be changed and/or remanufactured to potentially improve the eye margin. That is, the process of redesigning and manufacturing the package substrate 200 may incur significant amounts of time and/or resources to implement and deploy.

In an example embodiment, if it is determined that the eye margin of the test signal transmitted through the first interconnection pattern 220 does not meet the standard, a conductive pattern may be connected to the connection portion 240 of the first interconnection pattern 220 exposed through the opening 230. In such an embodiment, the conductive pattern may be connected to the middle of the first interconnection pattern 220 and function as an open stub.

As described above, by adding and/or changing the conductive pattern to the first interconnection pattern 220 with reference to the result of measuring the characteristics of the test signal sent and/or received through the first solder ball 280a, the characteristics of the signal transmitted to the first interconnection pattern 220, such as, but not limited to, the eye margin, may be improved. Therefore, in an example embodiment, during the test work process performed after the package substrate 200 is manufactured and the semiconductor chip is mounted, the characteristics of the signal transmitted to the plurality of interconnection patterns 220 may be improved without the redesign and reproduction process of the package substrate 200. In such a manner, the versatility of the package substrate 200 may be improved, and the manufacturing cost and/or production time of the semiconductor package including the package substrate 200 may be shortened, when compared to related package substrates.

In addition, by forming a conductive pattern functioning as an open stub, such as in the package substrate 200A, according to the example embodiment of FIG. 4, and the package substrate 200B, according to the example embodiment of FIG. 5, with a wire 290a and/or a metal nano ink pattern 290b, the length, shape, or the like of the conductive pattern may be variously selected even after the manufacture of the package substrate (e.g., the package substrate 200A or the package substrate 200B) is completed. Therefore, signal characteristics may be improved and the versatility of the package substrate may be improved by changing the length, shape, material, or the like of the conductive pattern without having to manufacture the package substrate itself again.

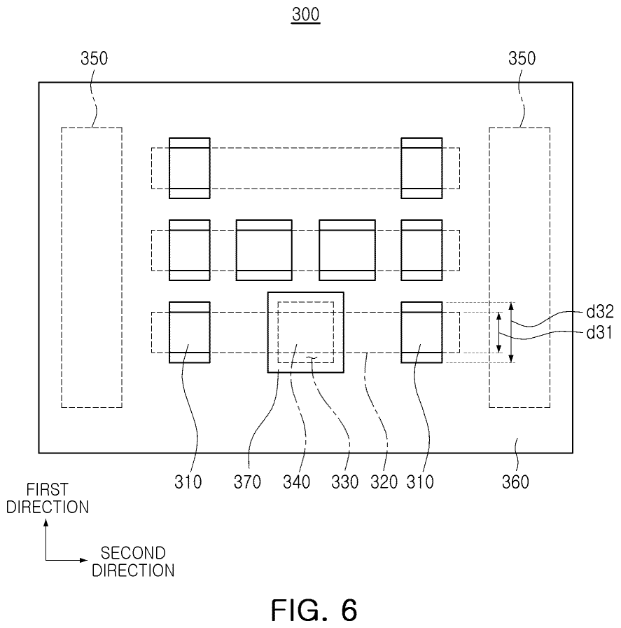

FIG. 6 is a drawing illustrating a package substrate, according to an example embodiment.

Referring to FIG. 6, a package substrate 300, according to an example embodiment, may include a base substrate, a plurality of chip connection pads 310, a plurality of interconnection patterns 320, an insulating layer 360 disposed on the plurality of interconnection patterns 320, and a dummy chip 370. The architecture of the package substrate 300 may be similar in many respects to the package substrate 200 described above with reference to FIGS. 2 and 3, and may include additional features not mentioned above. Some of the elements of the package substrate 300 described above have been omitted for the sake of simplicity.

The package substrate 300 may include a semiconductor chip mounting area 350 on which a semiconductor chip is mounted. The plurality of chip connection pads 310 may be disposed on the upper surface of the base substrate and may not be covered by the insulating layer 360, and as a result, may be exposed to the outside. The plurality of interconnection patterns 320 may be disposed on the upper surface of the base substrate and may be physically and electrically connected to the plurality of chip connection pads 310.

The insulating layer 360 may be disposed over the plurality of interconnection patterns 320 and may not be disposed over the plurality of chip connection pads 310. The insulating layer 360 may include at least one opening 330. The opening 330 may expose the connection portion 340, which is at least a portion of the first interconnection pattern 320 from among the plurality of interconnection patterns 320, to the outside.

The package substrate 300 may include a dummy chip 370. The dummy chip 370 may be disposed over the opening 330. Although FIG. 6 depicts the opening 330 as having a second width d32 longer than the first width d31 in the first direction, the present disclosure is not limited in this regard. For example, the opening 330 may also have the first width d31 in the first direction.

If the eye margin of the test signal measured by the test equipment connected to the package substrate 300, according to the example embodiment of FIG. 6, satisfies a predetermined standard, there may be no need to connect a separate conductive pattern to the connection portion 340. However, if the package substrate 300 is used in a state where the conductive pattern is not connected to the connection portion 340 and the first interconnection pattern 320 is exposed to the outside, the semiconductor package including the package substrate 300 may be defective due to defects such as, but not limited to, a short circuit, an open circuit, or the like in the internal circuit through the connection portion 340 exposed to the outside. Therefore, by disposing a dummy chip 370 over the opening 330, a defect may be prevented and/or reduced from occurring through a connection portion 340 to which the conductive pattern is not connected, when compared to a related package substrate.

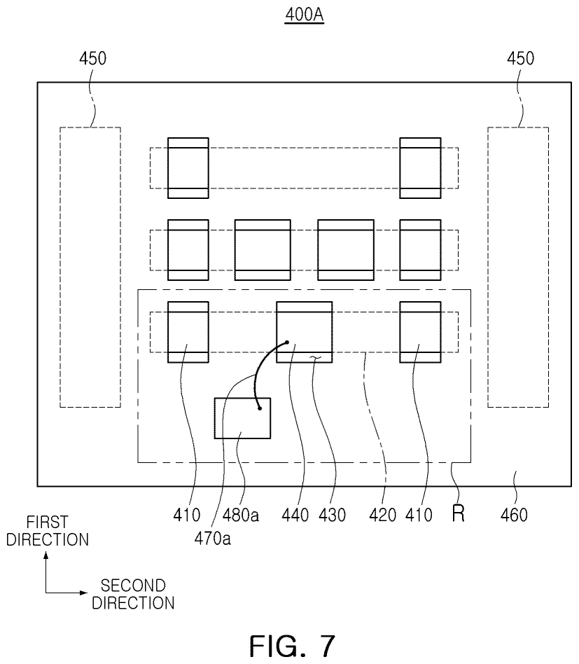

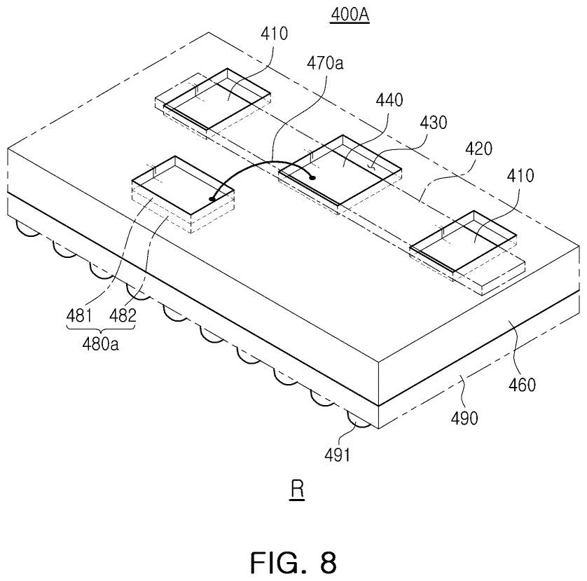

FIG. 7 is a drawing illustrating a package substrate, according to an example embodiment. FIG. 8 is a perspective view illustrating an enlarged portion R of FIG. 7.

Referring to FIGS. 7 and 8, a package substrate 400A, according to an example embodiment, may include a base substrate 490, a plurality of chip connection pads 410, a plurality of interconnection patterns 420, an insulating layer 460 disposed on the plurality of interconnection patterns 420, a plurality of dummy pads (e.g., a first dummy pad 480a, hereinafter generally referred to as “480”), a plurality of solder balls 491, and a wire 470a. The architecture of the package substrate 400A may be similar in many respects to the package substrate 200 described above with reference to FIGS. 2 and 3, and may include additional features not mentioned above. Some of the elements of the package substrate 400A described above have been omitted for the sake of simplicity.

The package substrate 400A may include a plurality of semiconductor chip mounting areas 450 on the upper portion. The plurality of chip connection pads 410 may be disposed on the upper surface of the base substrate 490 and may not be covered by the insulating layer 460, and as a result, may be exposed to the outside. A plurality of interconnection patterns 420 may be disposed on the upper surface of the base substrate 490 and may be physically and electrically connected to a plurality of chip connection pads 410.

An insulating layer 460 may be disposed on the plurality of interconnection patterns 420 and may not be disposed on the plurality of chip connection pads 410. The insulating layer 460 may include at least one opening 430. The opening 430 may expose a connection portion 440, which is at least a portion of a first interconnection pattern 420 from among the plurality of interconnection patterns 420, to the outside.

A first dummy pad 480a may be composed of an opening 481 from which the insulating layer 460 is removed and a conductive member 482. The conductive member 482 may be disposed on the base substrate 490 and may be electrically connected to the wire 470a.

The package substrate 400A may include a plurality of dummy pads 480 and a wire 470a. The first end of the wire 470a may be electrically connected to the connection portion 440. The second end of the wire 470a may be connected to the first dummy pad 480a. The number of wires 470a may vary depending on an example embodiment.

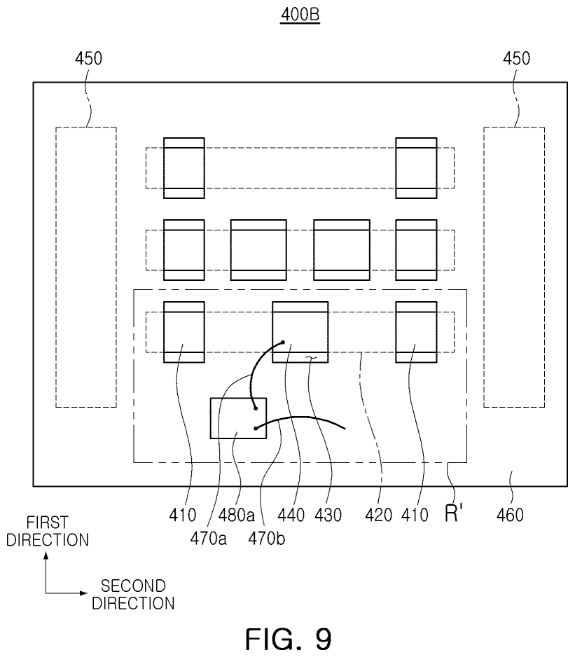

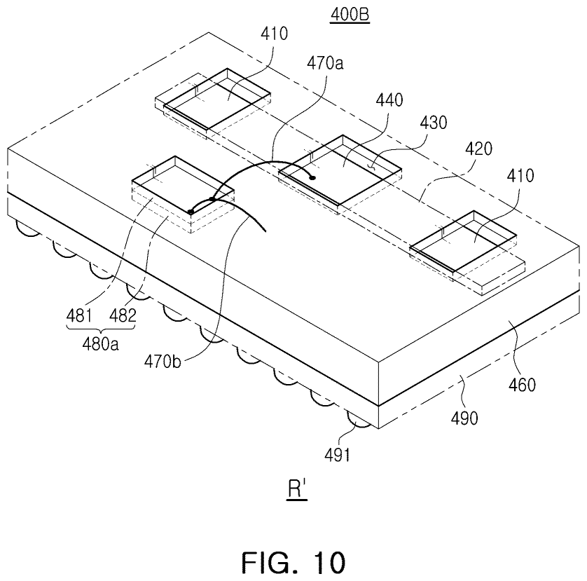

FIG. 9 is a drawing illustrating a package substrate, according to an example embodiment. FIG. 10 is a perspective view illustrating an enlarged portion R′ of FIG. 9. The architecture of the package substrate 400B may be similar in many respects to the package substrate 200 described above with reference to FIGS. 2 and 3, and may include additional features not mentioned above. Some of the elements of the package substrate 400B described above have been omitted for the sake of simplicity.

Referring to FIGS. 9 and 10, the package substrate 400B, according to an example embodiment, may further include an extension wire 470b when compared to the package substrate 400A. The wire 470a may have a first end electrically connected to the connection portion 440. The wire 470a may have a second end connected to a first dummy pad 480a. The extension wire 470b may be connected to the first dummy pad 480a. The number of wires 470a and extension wires 470b may vary depending on an example embodiment.

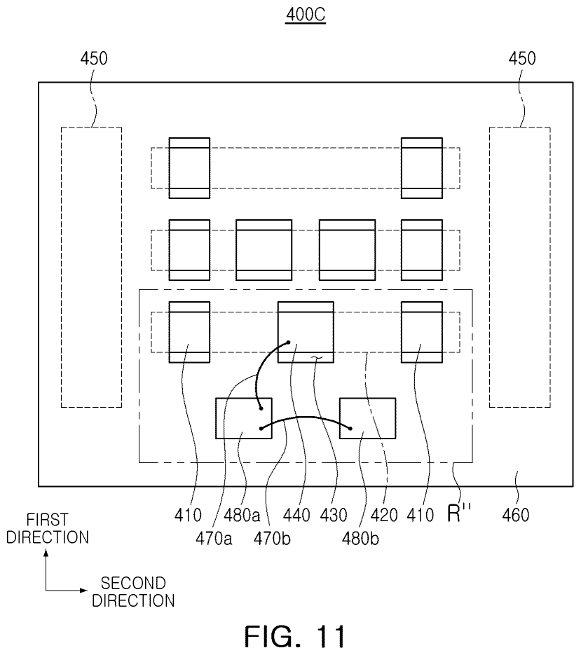

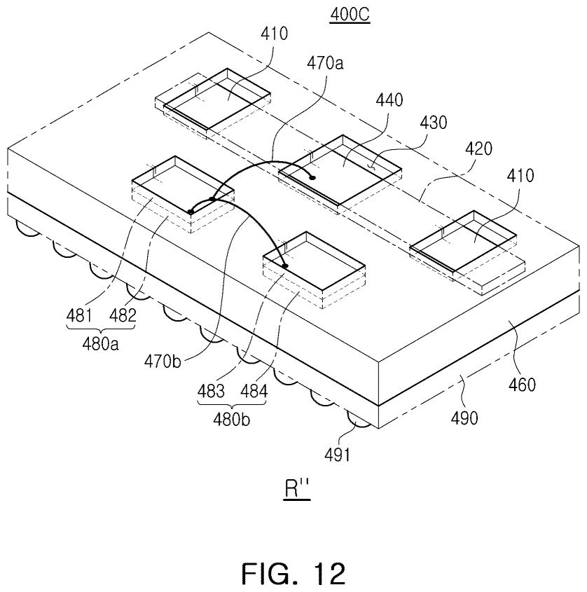

FIG. 11 is a drawing illustrating a package substrate, according to an example embodiment. FIG. 12 is a perspective view illustrating an enlarged portion R″ of FIG. 11. The architecture of the package substrate 400C may be similar in many respects to the package substrate 200 described above with reference to FIGS. 2 and 3, and may include additional features not mentioned above. Some of the elements of the package substrate 400C described above have been omitted for the sake of simplicity.

Referring to FIGS. 11 and 12, the package substrate 400C, according to an example embodiment, may further include an extension wire 470b and a plurality of dummy pads (e.g., a first dummy pad 480a and a second dummy pad 480b, hereinafter generally referred to as “480”), when compared to the package substrate 400A. The wire 470a may have a first end electrically connected to a connection portion 440. The wire 470a may have a second end connected to the first dummy pad 480a from among the plurality of dummy pads 480. The extension wire 470b may have a first end connected to the first dummy pad 480a. The extension wire 470b may have its second end connected to the second dummy pad 480b from among a plurality of dummy pads 480.

The plurality of dummy pads 480 may be composed of openings (e.g., a first opening 481 and a second opening 483) from which an insulating layer 460 has been removed and conductive members (e.g., a first conductive member 482 and a second conductive member 484). The first and second conductive members 482 and 484 may be disposed on a base substrate 490, and the first dummy pad 480a may be electrically connected to the wire 470a and the extension wire 470b, and the second dummy pad 480b may be electrically connected to the extension wire 470b. The number of the wire 470a, the extension wire 470b, and the plurality of dummy pads 480 may vary depending on an example embodiment.

As the wire 470a and the extension wire 470b functioning as open stubs may be exposed to the outside, the length, shape, or the like of the wire 470a and/or the extension wire 470b may be deformed due to external impact or the like, which may be a factor in causing a defect in the semiconductor package. In an example embodiment, the second end of the wire 470a and/or both ends of the extension wire 470b may be fixed through the plurality of dummy pads 480. Therefore, occurrence of defects in the semiconductor package caused by deformation of the wire 470a and/or the extension wire 470b may be prevented and/or reduced, when compared to related package substrates.

In an embodiment, a length of the wire 470a and/or the extension wire 470b may not be easily increased. In an example embodiment, when both ends of the wire 470a are fixed, an extension wire 470b may be further connected to the first dummy pad 480a that fixes the second end of the wire 470a. For example, the length of the open stub may be extended without deforming the wire 470a that may already be connected.

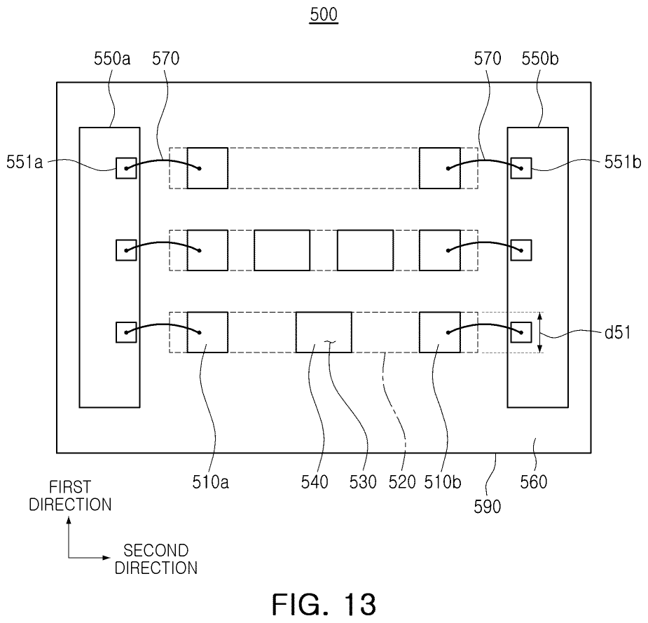

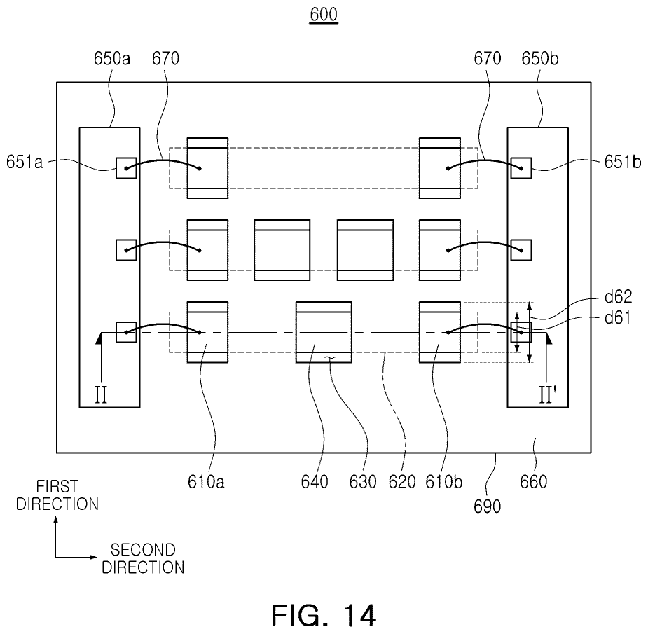

FIGS. 13 and 14 are drawings illustrating semiconductor packages, according to example embodiments.

Referring to FIG. 13, a semiconductor package 500, according to an example embodiment, may include a package substrate 590, a plurality of semiconductor chips (e.g., a first semiconductor chip 550a and a second semiconductor chip 550b, hereinafter generally referred to as “550”), or the like. The architecture of the package substrate 590 may be similar in many respects to the package substrate 200 described above with reference to FIGS. 2 and 3, and may include additional features not mentioned above. Some of the elements of the package substrate 590 described above have been omitted for the sake of simplicity.

The first interconnection pattern 520 may have a first width d51 in a first direction parallel to the upper surface of the base substrate. The width of the opening 530 in the first direction may be substantially the same as the first width d51 of the first interconnection pattern 520. At least one of the plurality of chip connection pads 510 (e.g., first chip connection pads 510a and second chip connection pads 510b) may have the first width d51 in the first direction.

The plurality of semiconductor chips 550 may be mounted on the package substrate. The plurality of semiconductor chips 550 may include the plurality of chip pads (e.g., a first chip pad 551a and a second chip pad 551b, hereinafter generally referred to as “551”). The first semiconductor chip 550a from among the plurality of semiconductor chips 550 may be electrically connected to the first chip pad 551a from among the plurality of chip pads 551, and the first chip connection pads 510a from among the plurality of chip connection pads 510 through the bonding wire 570. Among the plurality of semiconductor chips, a second semiconductor chip 550b may be electrically connected to the second chip pad 551b from among the plurality of chip pads 551 and second chip connection pads 510b from among the plurality of chip connection pads 510 through a bonding wire 570.

Referring to FIG. 14, a semiconductor package 600, according to an example embodiment, may include a package substrate 690, a plurality of semiconductor chips (e.g., a first semiconductor chip 650a and a second semiconductor chip 650b, hereinafter generally referred to as “650”), or the like. The architecture of the package substrate 690 may be similar in many respects to the package substrate 200 described above with reference to FIGS. 2 and 3, and may include additional features not mentioned above. Some of the elements of the package substrate 690 described above have been omitted for the sake of simplicity.

The first interconnection pattern 620 may have a first width d61 in a first direction parallel to the upper surface of the base substrate. The opening 630 may have a second width d62 longer than the first width d61 in the first direction. At least one of the plurality of chip connection pads 610 may have the first width d61 in the first direction.

The plurality of semiconductor chips 650 may be mounted on the package substrate 690. The plurality of semiconductor chips 650 may include a plurality of chip pads (e.g., a first chip pad 651a and a second chip pad 651b, hereinafter generally referred to as “650”). Among the plurality of semiconductor chips 650, the first semiconductor chip 650a may be electrically connected to the first chip pad 651a from among the plurality of chip pads 651 and a first chip connection pad 610a from among the plurality of chip connection pads through a bonding wire 670. The second semiconductor chip 650b from among the plurality of semiconductor chips 650 may be electrically connected to the second chip pad 651b from among the plurality of chip pads 651 and a second chip connection pad 610b from among the plurality of chip connection pads through a bonding wire 670.

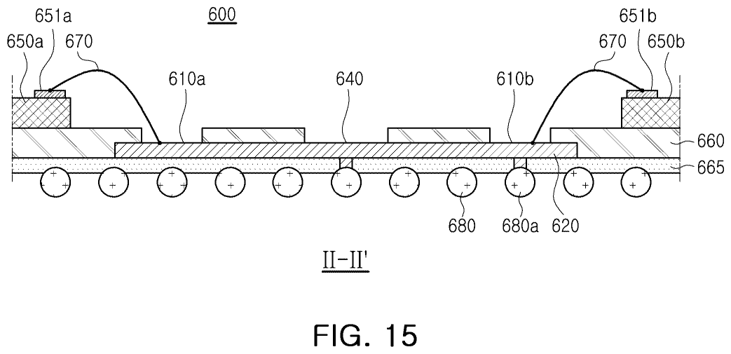

FIG. 15 is a cross-sectional view illustrating the semiconductor package 600 of FIG. 14 taken along line II-II′, according to an example embodiment.

The cross-sectional structure described with reference to FIG. 15 may also be applied to a semiconductor package 500 including a package substrate 590 in which an opening 530 has a first width d51 equal to an interconnection pattern 520, as shown in FIG. 13.

Referring to FIG. 15, the semiconductor package 600, according to an example embodiment, may include a package substrate, the plurality of semiconductor chips 650, or the like. The package substrate may include a base substrate 665, a plurality of chip connection pads (e.g., the first chip connection pad 610a and the second chip connection pad 610b), a plurality of interconnection patterns 620, an insulating layer 660 disposed on the plurality of interconnection patterns 620, a plurality of solder balls 680, or the like. The plurality of solder balls 680 may be disposed under the base substrate 665. At least one of the plurality of solder balls 680 (e.g., the first solder ball 680a) may be electrically connected to the first interconnection pattern 620.

The plurality of semiconductor chips 650 may be mounted on the package substrate. The first semiconductor chip 650a of the plurality of semiconductor chips 650 may be electrically connected to the first chip pad 651a of the plurality of chip pads 651 and the first chip connection pads 610a of the plurality of first and second chip connection pads 610a and 610b through the bonding wire 670. Among the plurality of semiconductor chips 650, the second semiconductor chip 650b may be electrically connected to the second chip pad 651b from among the plurality of chip pads 651 and the second chip connection pads 610b from among the plurality of first and second chip connection pads 610a and 610b through a bonding wire 670.

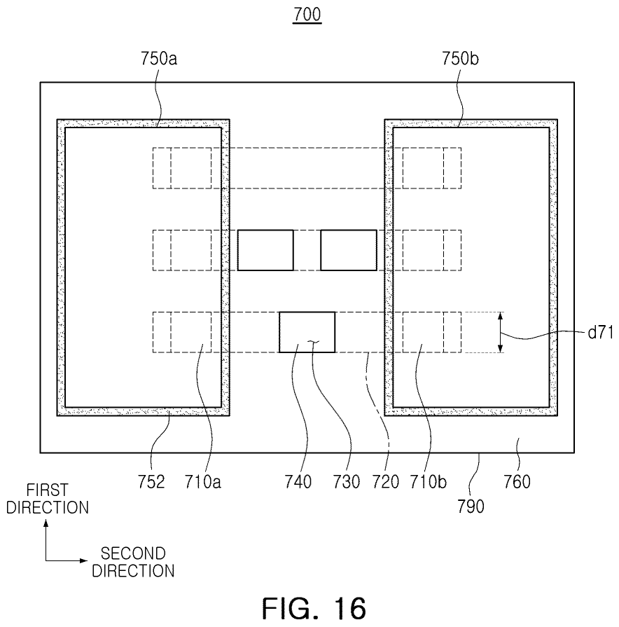

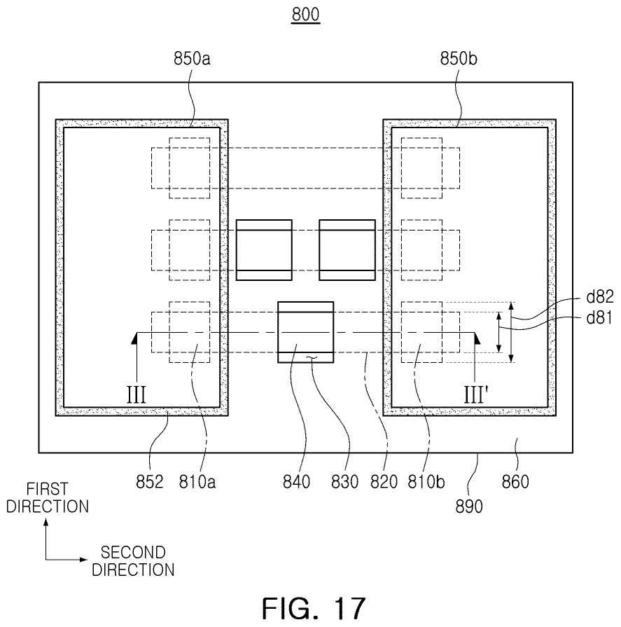

FIGS. 16 and 17 are drawings illustrating semiconductor packages, according to example embodiments.

Referring to FIG. 16, a semiconductor package 700, according to an example embodiment, may include a package substrate 790, a plurality of semiconductor chips (e.g., a first semiconductor chip 750a and a second semiconductor chip 750b, hereinafter generally referred to as “750”), or the like. The architecture of the package substrate 790 may be similar in many respects to the package substrate 200 described above with reference to FIGS. 2 and 3, and may include additional features not mentioned above. Some of the elements of the package substrate 790 described above have been omitted for the sake of simplicity.

The first interconnection pattern 720 may have a first width d71 in a first direction parallel to the upper surface of the base substrate. The width of the opening 730 in the first direction may be substantially similar and/or the same as the first width d71 of the first interconnection pattern 720. At least one of the plurality of chip connection pads 710 may have the first width d71 in the first direction.

The plurality of semiconductor chips 750 may be mounted on the package substrate 790. An underfill 752 may be applied between the plurality of semiconductor chips 750 and the package substrate 790. The first semiconductor chip 750a of the plurality of semiconductor chips 750 may be connected to first chip connection pads 710a of a plurality of chip connection pads through microbumps. Among the plurality of semiconductor chips 750, the second semiconductor chip 750b may be connected to second chip connection pads 710b from among the plurality of chip connection pads through microbumps.

Referring to FIG. 17, a semiconductor package 800, according to an example embodiment, may include a package substrate 890, a plurality of semiconductor chips (e.g., a first semiconductor chip 850a and a second semiconductor chip 850b, hereinafter generally referred to as “850”), or the like. The architecture of the package substrate 890 may be similar in many respects to the package substrate 200 described above with reference to FIGS. 2 and 3, and may include additional features not mentioned above. Some of the elements of the package substrate 890 described above have been omitted for the sake of simplicity.

The first interconnection pattern 820 may have a first width d81 in a first direction parallel to the upper surface of the base substrate. The opening 830 may have a second width d82 longer than the first width d81 in the first direction. At least one of the plurality of chip connection pads 810 may have the first width d81 in the first direction.

The plurality of semiconductor chips 850 may be mounted on the package substrate 890. An underfill 852 may be applied between a plurality of semiconductor chips 850 and a package substrate 890. A first semiconductor chip 850a from among the plurality of semiconductor chips 850 may be connected to first chip connection pads 810a from among a plurality of chip connection pads through microbumps. A second semiconductor chip 850b from among the plurality of semiconductor chips 850 may be connected to second chip connection pads 810b from among the plurality of chip connection pads through microbumps.

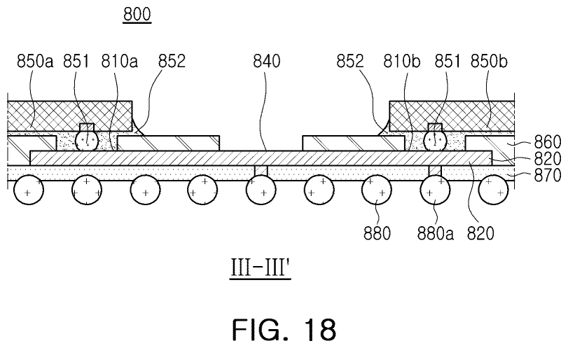

FIG. 18 is a cross-sectional view illustrating the package substrate of FIG. 17 taken along line III-III′, according to an example embodiment.

The cross-sectional structure described with reference to FIG. 18 may also be applied to a semiconductor package 700 including a package substrate 790 having an opening 730 that has the same first width d71 as the width of the interconnection pattern 720 as illustrated in FIG. 16.

Referring to FIG. 18, a semiconductor package 800, according to an example embodiment, may include a package substrate and a plurality of semiconductor chips (e.g., a first semiconductor chip 850a and a second semiconductor chip 850b, hereinafter generally referred to as “850”). The package substrate may include a base substrate 870, a plurality of chip connection pads (e.g., a first chip connection pad 810a and a second chip connection pad 810b, hereinafter generally referred to as “810”), a plurality of interconnection patterns 820, an insulating layer 860 disposed on the plurality of interconnection patterns 820, and a plurality of solder balls 880. The plurality of solder balls 880 may be disposed under the base substrate 870. At least one of the plurality of solder balls 880 (e.g., the first solder ball 880a) may be electrically connected to the first interconnection pattern 820 and may be electrically connected to the test pad.

The plurality of semiconductor chips 850 may be mounted on the package substrate. The plurality of semiconductor chips 850 may include a plurality of microbumps 851. The first semiconductor chip 850a from among the plurality of semiconductor chips 850 may be electrically connected to the first chip connection pad 810a through the micro bump 851. The second semiconductor chip 850b from among the plurality of semiconductor chips 850 may be electrically connected to the second chip connection pad 810b through the micro bump 851.

In an example embodiment, the first semiconductor chip 850a may transmit a signal to the second semiconductor chip 850b, and/or may receive a signal from the second semiconductor chip 850b. For example, the signal transmitted by the first semiconductor chip 850a may be a data signal. As another example, the first semiconductor chip 850a may be and/or may include a NAND flash memory, and the second semiconductor chip 850b may be and/or may include a memory controller. However, the present disclosure is not limited as to the types of the plurality of semiconductor chips 850. For example, the plurality of semiconductor chips may be and/or may include various other types of semiconductor chips without departing from the scope of the present disclosure.

In an example embodiment, the first interconnection pattern 820 may be electrically connected to the first solder ball 880a, so that the first semiconductor chip 850a may be electrically connected to the test pad. The first semiconductor chip 850a may transmit a signal to the test pad, and/or may receive a signal from the test pad. For example, the first semiconductor chip 850a may be and/or may include a NAND flash memory. However, the present disclosure is not limited as to the types of the plurality of semiconductor chips 850. For example, the plurality of semiconductor chips may be and/or may include various other types of semiconductor chips without departing from the scope of the present disclosure.

The plurality of semiconductor chips 850 may send and/or receive signals through the plurality of interconnection patterns 820. Before the semiconductor package is shipped, a test operation may be performed to check whether the plurality of semiconductor chips 850 are properly mounted on the package substrate, whether there is an abnormality in the package manufacturing process, or the like. To this end, the plurality of interconnection patterns 820 may be connected to the test pad through the first solder balls 880a.

If the test equipment detects that the characteristics (e.g., the eye margin) of the test signal does not meet a predetermined standard while performing the test operation, it may be determined that there is a defect in the first interconnection pattern 820. For example, if the eye margin of the data signal transmitted by the first semiconductor chip 850a to the second semiconductor chip 850b through the first interconnection pattern 820 decreases, data in the signal may be lost during the process of exchanging the data signal.

In an embodiment, if it is determined that the eye margin of the test signal transmitted through the first interconnection pattern 820 does not meet the standard, the design of the package substrate may be changed and remanufactured to attempt to improve the eye margin. However, the process of redesigning and manufacturing the package substrate may incur significant amounts of time and/or resources to implement and deploy.

In an example embodiment, if it is determined that the eye margin of the test signal transmitted through the first interconnection pattern 820 does not meet the standard, a conductive pattern may be connected to the connection portion 840 of the first interconnection pattern 820 exposed through the opening 830. In such an embodiment, the conductive pattern may be connected to the middle of the first interconnection pattern 820 to function as an open stub.

As described above, by referring to the result of measuring the characteristics of the test signal transmitted and received through the first solder ball 880a, the characteristics such as, but not limited to, the eye margin of the signal transmitted through the first interconnection pattern 820 may be improved by connecting the conductive pattern to the first interconnection pattern 820 and/or changing the connected conductive pattern. Therefore, in an example embodiment, during the test work process performed before the package substrate is manufactured and the semiconductor chip is mounted and shipped, the characteristics of the signal transmitted through the plurality of interconnection patterns 820 may be improved without the redesign and reproduction process of the package substrate. In such a manner, the versatility of the package substrate may be improved, and the manufacturing cost and production time of the semiconductor package 800 including the package substrate may be shortened, when compared to related package substrates.

As set forth above, according to an example embodiment, a portion of an insulating layer disposed on an interconnection pattern may be removed to expose a connection portion that is a portion of the interconnection pattern, and a wire may be selectively connected to the interconnection pattern through the connection portion. Accordingly, even after the manufacturing of the package substrate is completed, by changing whether the wire is connected, the length of the wire, or the like, characteristics of a signal transmitted to the interconnection pattern may be optimized, and thereby a package substrate having a relatively high versatility and/or reliability may be provided.

While example embodiments have been illustrated and described above, it may be apparent to those skilled in the art that modifications and variations could be made without departing from the scope of the present disclosure as defined by the appended claims.

What is claimed is:

1. A package substrate, comprising:
a base substrate;
a plurality of chip connection pads on an upper surface of the base substrate;
a plurality of interconnection patterns on the upper surface of the base substrate and coupled with the plurality of chip connection pads; and
an insulating layer on the plurality of interconnection patterns,
wherein the insulating layer comprises a solder resist layer and at least one opening,
wherein the at least one opening at least partially exposes a connection portion, and
wherein the connection portion comprises at least a portion of a first interconnection pattern from among the plurality of interconnection patterns.

2. The package substrate of claim 1, wherein a first width of the first interconnection pattern in a first direction is equal to a second width of the at least one opening in the first direction, and
wherein the first direction is parallel to the upper surface of the base substrate.

3. The package substrate of claim 2, wherein a third width of at least one connection pad of the plurality of chip connection pads in the first direction is equal to the first width.

4. The package substrate of claim 1, wherein a first width of the first interconnection pattern in a first direction is less than a second width of the at least one opening in the first direction, and
wherein the first direction is parallel to the upper surface of the base substrate.

5. The package substrate of claim 4, wherein a third width of at least one connection pad of the plurality of chip connection pads in the first direction is equal to the first width.

6. The package substrate of claim 1, further comprising:
at least one wire coupled with the connection portion.

7. The package substrate of claim 6, further comprising:
at least one dummy pad on a same layer as the plurality of chip connection pads.

8. The package substrate of claim 7, wherein a first end of the at least one wire is coupled with the first interconnection pattern, and
wherein a second end of the at least one wire different from the first end is coupled with the at least one dummy pad.

9. The package substrate of claim 8, further comprising an extension wire coupled with the at least one dummy pad.

10. The package substrate of claim 7, wherein the at least one dummy pad comprises a first dummy pad disposed at a first position and a second dummy pad disposed at a second position different from the first position,
wherein the at least one wire comprises a wire coupled with the first interconnection pattern at the connection portion and coupled with the first dummy pad, and
wherein the package substrate further comprises an extension wire coupled with the first dummy pad and the second dummy pad.

11. The package substrate of claim 1, further comprising:
a plurality of solder balls,
wherein at least one of the plurality of solder balls is coupled with the first interconnection pattern and a test pad.

12. The package substrate of claim 1, further comprising:
a dummy chip disposed over the at least one opening.

13. The package substrate of claim 1, further comprising:
a metal nano ink pattern coupled with the connection portion.

14. The package substrate of claim 13, wherein the metal nano ink pattern comprises silver (Ag).

15. A semiconductor package, comprising:
a package substrate comprising:
a base substrate;
a plurality of chip connection pads on an upper surface of the base substrate;
a plurality of interconnection patterns on the upper surface of the base substrate and coupled with the plurality of chip connection pads; and
an insulating layer on a surface of the plurality of interconnection patterns, the insulating layer comprising at least one opening, the at least one opening at least partially exposing a connection portion, the connection portion comprising at least a portion of a first interconnection pattern from among the plurality of interconnection patterns; and
a plurality of semiconductor chips mounted on an upper portion of the package substrate,
wherein a first semiconductor chip from among the plurality of semiconductor chips is coupled with first chip connection pads from among the plurality of chip connection pads, and
wherein a second semiconductor chip from among the plurality of semiconductor chips is coupled with second chip connection pads from among the plurality of chip connection pads.

16. The semiconductor package of claim 15, wherein the first semiconductor chip is configured to transmit a data signal to the second semiconductor chip through the first interconnection pattern.

17. The semiconductor package of claim 16, wherein the first semiconductor chip comprises a NAND flash memory, and
wherein the second semiconductor chip comprises a memory controller.

18. A semiconductor package, comprising:
a package substrate comprising:
a base substrate;
a plurality of chip connection pads on an upper surface of the base substrate;
a plurality of interconnection patterns on the upper surface of the base substrate and coupled with the plurality of chip connection pads; and
an insulating layer on a surface of the plurality of interconnection patterns, the insulating layer comprising at least one or more openings, at least one of the at least one or more openings at least partially exposing a connection portion, the connection portion comprising at least a portion of a first interconnection pattern from among the plurality of interconnection patterns;
a plurality of semiconductor chips mounted on an upper portion of the package substrate; and
a plurality of solder balls comprising a first solder ball,
wherein the first solder ball is coupled with the first interconnection pattern and a test pad.

19. The semiconductor package of claim 18, wherein a first semiconductor chip from among the plurality of semiconductor chips is coupled with at least one first chip connection pad from among the plurality of chip connection pads, and
wherein the first semiconductor chip is configured to a data signal to the first solder ball.

20. The semiconductor package of claim 19, wherein the first semiconductor chip comprises a NAND flash memory.
